(19) United States
(12) Patent Application Publication
(10) Pub. No.: US 2008/0316823 A1
(43) Pub. Date: Dec. 25, 2008

(54) STORAGE DEVICE AND CIRCUIT ELEMENT SWITCHING METHOD THEREOF

(76) Inventors: Tzu-Shen Chen, Hsinchu City (TW); Chun-Hsien Lin, Hsinchu City (TW); Ming-Hsien Huang, Tainan County (TW)

Correspondence Address: NORTH AMERICA INTELLECTUAL PROPERTY CORPORATION, P.O. BOX 506, MERRIFIELD, VA, 22116, US

(21) Appl. No.: 11/781,957

(22) Filed: Jul. 24, 2007

(30) Foreign Application Priority Data
Jun. 23, 2007 (TW) 096122794

(51) Int. Cl. G11C 11/34

(52) U.S. Cl. 365/185.11

(57) ABSTRACT

The present invention discloses a storage device and a circuit element switching method thereof. The storage device includes: a plurality of memory modules, wherein each of the plurality of memory modules includes a plurality of chip enable terminals; a memory control unit that includes a plurality of bank selection terminals; and a switch module that is coupled between the plurality of memory modules and the memory control unit, and utilized for dispersedly coupling the plurality of bank selection terminals to the plurality of chip enable terminals of each of the plurality of memory modules. The circuit element switching method applied to the storage device includes: providing a memory control unit including a plurality of bank selection terminals; and dispersedly coupling the plurality of bank selection terminals to a plurality of chip enable terminals of each of the plurality of memory modules.

### BACKGROUND OF THE INVENTION

1. Field of the Invention

The present invention relates to a storage device and a circuit element switching method thereof, and more particularly, to a storage device and a circuit element switching method thereof that are capable of utilizing an interconnection scheme with elastic flexibility to averagely and separately couple a specific amount of bank selection terminals of a memory control unit to a plurality of chip enable terminals of each of a plurality of memory modules.

2. Description of the Prior Art

Please refer to FIG. 1. FIG. 1 shows a simplified block diagram of a conventional solid state drive (SSD) 100 using a plurality of non-volatile memory modules, such as a plurality of NAND type flash memory modules. As shown in FIG. 1, the SSD 100 includes a first NAND type flash memory module 111, a second NAND type flash memory module 112, a third NAND type flash memory module 113, a fourth NAND type flash memory module 114, a fifth NAND type flash memory module 115, a sixth NAND type flash memory module 116, a seventh NAND type flash memory module 117, an eighth NAND type flash memory module 118, and a memory control integrated circuit (IC) 120, wherein all of the first NAND type flash memory module 111, the second NAND type flash memory module 112, the third NAND type flash memory module 113, the fourth NAND type flash memory module 114, the fifth NAND type flash memory module 115, the sixth NAND type flash memory module 116, the seventh NAND type flash memory module 117, and the eighth NAND type flash memory module 118 respectively include four chip enable terminals CE0, CE1, CE1, and CE3 (not shown). If the memory control IC 120 has 32 bank selection terminals (not shown), then the conventional circuit element switching method in the conventional SSD 100 will couple the 32 bank selection terminals to the respective four chip enable terminals CE0, CE1, CE1, and CE3 of each of the first NAND type flash memory module 111, the second NAND type flash memory module 112, the third NAND type flash memory module 113, the fourth NAND type flash memory module 114, the fifth NAND type flash memory module 115, the sixth NAND type flash memory module 116, the seventh NAND type flash memory module 117, and the eighth NAND type flash memory module 118 respectively.

However, If the memory control IC 120 only has 16 bank selection terminals (not shown), then the conventional circuit element switching method in the conventional SSD 100 will couple the 16 bank selection terminals to the respective four chip enable terminals CE0, CE1, CE1, and CE3 of each of the first NAND type flash memory module 111, the second NAND type flash memory module 112, the third NAND type flash memory module 113, and the fourth NAND type flash memory module 114 respectively. It is thus quite obvious that the conventional SSD 100 is not capable of utilizing the fifth NAND type flash memory module 115, the sixth NAND type flash memory module 116, the seventh NAND type flash memory module 117, and the eighth NAND type flash memory module 118. In addition, in a practical condition, there is a high possibility that there is only one available chip enable terminal CE0 in the respective four chip enable terminals CE0, CE1, CE1, and CE3 of each of the first NAND type flash memory module 111 (please note that the “module” herein is also known as the “semiconductor package device”), the second NAND type flash memory module 112, the third NAND type flash memory module 113, the fourth NAND type flash memory module 114, the fifth NAND type flash memory module 115, the sixth NAND type flash memory module 116, the seventh NAND type flash memory module 117, and the eighth NAND type flash memory module 118 is coupled to a NAND type flash memory chip (not shown) and the other three chip enable terminals CE1, CE2, and CE3 are left unused for the moment. The three unused chip enable terminals CE1, CE2, and CE3 will be utilized when there are more NAND type flash memory chips implemented in the future. Many SSD manufacturers have some considerations about the product cost, market requirements, and upgrading product lines in the future, and thus the condition mentioned above is very common. Because of these reasons, the conventional SSD 100 and the conventional circuit element switching method thereof mentioned above will only let the respective one chip enable NAND type flash memory chip of each of the first NAND type flash memory module 111, the second NAND type flash memory module 112, the third NAND type flash memory module 113, and the fourth NAND type flash memory module 114 in the first NAND type flash memory module 111, the second NAND type flash memory module 112, the third NAND type flash memory module 113, the fourth NAND type flash memory module 114, the fifth NAND type flash memory module 115, the sixth NAND type flash memory module 116, the seventh NAND type flash memory module 117, and the eighth NAND type flash memory module 118 be utilized in practice. In other words, the conventional SSD 100 only utilizes 4 bank selection terminals in the 16 bank selection terminals of the memory control IC 120 in practice and the operational utilities of the other 16 bank selection terminals are wasted, and thus the conventional SSD 100 is not capable of utilizing the respective one chip enable NAND type flash memory chip of each of the fifth NAND type flash memory module 115, the sixth NAND type flash memory module 116, the seventh NAND type flash memory module 117, and the eighth NAND type flash memory module 118. Therefore, it is very obvious that the conventional SSD 100 and the conventional circuit element switching method thereof mentioned above have not been capable of attaining the maximum storage capacity in the various different product design schemes nowadays.

### SUMMARY OF THE INVENTION

It is therefore one of the objectives of the present invention to provide a storage device and a circuit element switching method thereof that are capable of utilizing an interconnection scheme with elastic flexibility to averagely and separately couple a specific amount of bank selection terminals of a memory control unit to a plurality of chip enable terminals of each of a plurality of memory modules, so as to solve the above problem.

In accordance with an embodiment of the present invention, a storage device is disclosed. The storage device includes a plurality of memory modules, a memory control unit, and a switch module, wherein each of the plurality of memory modules includes a plurality of chip enable terminals; the memory control unit includes a specific amount of bank selection terminals; and the switch module is coupled between the plurality of memory modules and the memory control unit, and the switch module is utilized for dispersedly coupling the specific amount of bank selection terminals to the plurality of chip enable terminals of each of the plurality of memory modules. Wherein, the plurality of memory modules includes a plurality of NAND type flash memory modules and the storage device includes a solid state drive (SSD).

In accordance with an embodiment of the present invention, a circuit element switching method applied to a storage device is disclosed, wherein the storage device includes a plurality of memory modules, and each of the plurality of memory modules includes a plurality of chip enable terminals. The circuit element switching method includes: providing a memory control unit comprising a specific amount of bank selection terminals; and dispersedly coupling the specific amount of bank selection terminals to a plurality of chip enable terminals of each of the plurality of memory modules. Wherein, the plurality of memory modules includes a plurality of NAND type flash memory modules and the storage device includes a solid state drive (SSD).

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a simplified block diagram of a conventional solid state drive (SSD) using a plurality of non-volatile memory modules, such as a plurality of NAND type flash memory modules.

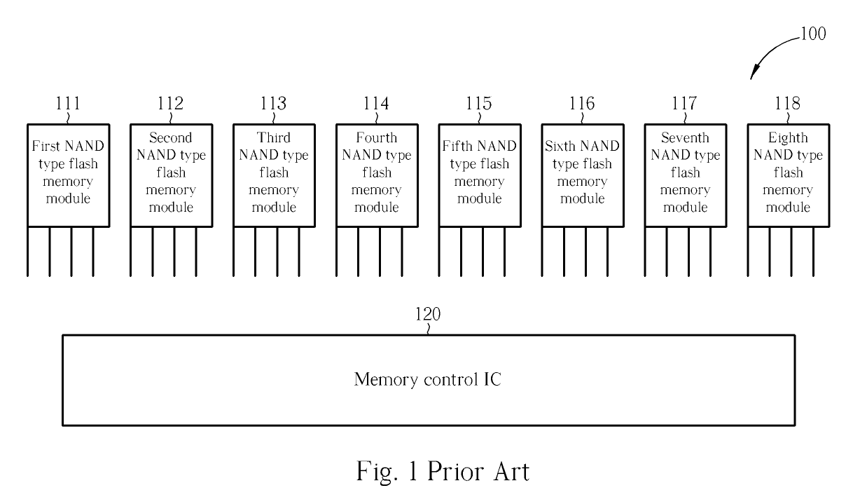

FIG. 2 shows a simplified block diagram of an SSD in accordance with an embodiment of the present invention.

FIG. 3 shows a simplified block diagram of an SSD in accordance with an embodiment of the present invention utilized with a circuit element switching method in accordance with a first embodiment of the present invention together.

FIG. 4 shows a simplified block diagram of an SSD in accordance with an embodiment of the present invention utilized with the circuit element switching method in accordance with the first embodiment of the present invention together.

FIG. 5 shows a simplified block diagram of an SSD in accordance with an embodiment of the present invention utilized with the circuit element switching method in accordance with the first embodiment of the present invention together.

FIG. 6 shows a simplified block diagram of an SSD in accordance with an embodiment of the present invention utilized with a circuit element switching method in accordance with a second embodiment of the present invention together.

FIG. 7 shows a simplified block diagram of an SSD in accordance with an embodiment of the present invention utilized with the circuit element switching method in accordance with the second embodiment of the present invention together.

FIG. 8 shows a simplified block diagram of an SSD in accordance with an embodiment of the present invention utilized with the circuit element switching method in accordance with the second embodiment of the present invention together.

FIG. 9 is a flowchart showing a circuit element switching method applied to a storage device in accordance with the operation schemes of the SSD in the above embodiments of the present invention.

### DETAILED DESCRIPTION

Certain terms are used throughout the following description and the claims to refer to particular system components. As one skilled in the art will appreciate, manufacturers may refer to a component by different names. This document does not intend to distinguish between components that differ in name but not differ in functionality. In the following discussion and in the claims, the terms “include”, “including”, “comprise”, and “comprising” are used in an open-ended fashion, and thus should be interpreted to mean “including, but not limited to . . . ” The terms “couple” and “coupled” are intended to mean either an indirect or a direct electrical connection. Thus, if a first device couples to a second device, that connection may be through a direct electrical connection, or through an indirect electrical connection via other devices and connections.

The present invention relates to a storage device and a circuit element switching method thereof that are capable of utilizing an interconnection scheme with elastic flexibility to averagely and separately couple a specific amount of bank selection terminals of a memory control unit to a plurality of chip enable terminals of each of a plurality of memory modules. This document will illustrate several exemplary embodiments that apply the storage device and the circuit element switching method thereof in the present invention. However, a person of average skill in the pertinent art should be able to understand that the present invention can be applied for various similar types of storage devices and is not limited to the particular embodiments described in the following paragraphs or to the particular manner in which any features of such embodiments are implemented.

In general, the circuit element switching method of the present invention can be applied to all kinds of storage devices. By way of example but not limitation, a circuit element switching method applied to a solid state drive (SSD) including a plurality of NAND type flash memory modules is disclosed in accordance with the present invention. In addition, under a condition of not affecting the technical disclosure of the present invention, an SSD including eight NAND type flash memory modules will be used as an example to illustrate the storage device and the circuit element switching method thereof in the present invention.

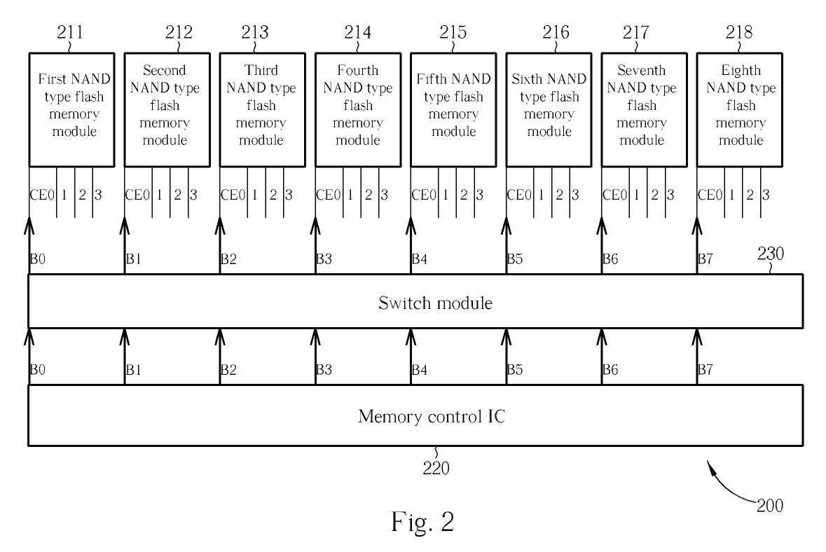

Please refer to FIG. 2. FIG. 2 shows a simplified block diagram of an SSD 200 in accordance with an embodiment of the present invention. As shown in FIG. 2, the SSD 200 includes a first NAND type flash memory module 211, a second NAND type flash memory module 212, a third NAND type flash memory module 213, a fourth NAND type flash memory module 214, a fifth NAND type flash memory module 215, a sixth NAND type flash memory module 216, a seventh NAND type flash memory module 217, an eighth NAND type flash memory module 218, a memory control integrated circuit (IC) 220, and a switch module 230, wherein all of the first NAND type flash memory module 211, the second NAND type flash memory module 212, the third NAND type flash memory module 213, the fourth NAND type flash memory module 214, the fifth NAND type flash memory module 215, the sixth NAND type flash memory module 216, the seventh NAND type flash memory module 217, and the eighth NAND type flash memory module 218 respectively include four chip enable terminals CE0, CE1, CE2, and CE3, and the switch module 230 can include a switch unit or a plurality of switch units (not shown). If the memory control IC 220 has 8 bank selection terminals B0, B1, B2, B3, B4, B5, B6, and B7, then the circuit element switching method in accordance with a first embodiment of the present invention will utilize the switch module 230 in the SSD 200 to averagely and separately couple the 8 bank selection terminals B0, B1, B2, B3, B4, B5, B6, and B7 to the respective chip enable terminal CE0 of each of the first NAND type flash memory module 211, the second NAND type flash memory module 212, the third NAND type flash memory module 213, the fourth NAND type flash memory module 214, the fifth NAND type flash memory module 215, the sixth NAND type flash memory module 216, the seventh NAND type flash memory module 217, and the eighth NAND type flash memory module 218. In this way, when there is only one chip enable terminal CE0 in the respective four chip enable terminals CE0, CE1, CE2, and CE3 of each of the first NAND type flash memory module 211, the second NAND type flash memory module 212, the third NAND type flash memory module 213, the fourth NAND type flash memory module 214, the fifth NAND type flash memory module 215, the sixth NAND type flash memory module 216, the seventh NAND type flash memory module 217, and the eighth NAND type flash memory module 218 is coupled to a NAND type flash memory chip (not shown) and the other three chip enable terminals CE1, CE2, and CE3 are left unused for the moment, then the SSD 200 and the circuit element switching method in accordance with the first embodiment of the present invention can efficiently make use of the respective NAND type flash memory chip of each of the first NAND type flash memory module 211, the second NAND type flash memory module 212, the third NAND type flash memory module 213, the fourth NAND type flash memory module 214, the fifth NAND type flash memory module 215, the sixth NAND type flash memory module 216, the seventh NAND type flash memory module 217, and the eighth NAND type flash memory module 218 by only utilizing the memory control IC 220 having 8 bank selection terminals and the switch module 230, so as to attain a maximum storage capacity. Unlike the conventional SSD and the flash memory module switching method, the conventional SSD and the flash memory module switching method have to utilize a memory control IC having 32 bank selection terminals so as to attain the maximum storage capacity mentioned above.

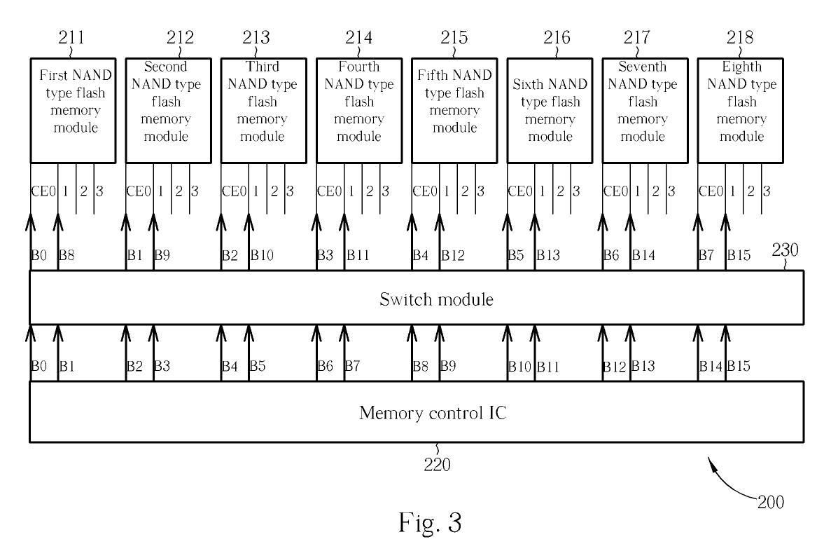

In a similar way, when there are only two chip enable terminals CE0 and CE1 in the respective four chip enable terminals CE0, CE1, CE2, and CE3 of each of the first NAND type flash memory module 211, the second NAND type flash memory module 212, the third NAND type flash memory module 213, the fourth NAND type flash memory module 214, the fifth NAND type flash memory module 215, the sixth NAND type flash memory module 216, the seventh NAND type flash memory module 217, and the eighth NAND type flash memory module 218 are respectively coupled to a NAND type flash memory chip (not shown) and the other two chip enable terminals CE2 and CE3 are left unused for the moment, then reasoning by analogy, the SSD 200 and the circuit element switching method in accordance with the first embodiment of the present invention can efficiently make use of the respective two NAND type flash memory chips of each of the first NAND type flash memory module 211, the second NAND type flash memory module 212, the third NAND type flash memory module 213, the fourth NAND type flash memory module 214, the fifth NAND type flash memory module 215, the sixth NAND type flash memory module 216, the seventh NAND type flash memory module 217, and the eighth NAND type flash memory module 218 by only utilizing the memory control IC 220 having 16 bank selection terminals B0, B1, B2, B3, B4, B5, B6, B7, B8, B9, B10, B11, B12, B13, B14, and B15 and the switch module 230, so as to attain a maximum storage capacity. Wherein, the circuit element switching method in accordance with the first embodiment of the present invention utilizes the switch module 230 in the SSD 200 to averagely and separately couple the 8 bank selection terminals B0, B1, B2, B3, B4, B5, B6, and B7 of the 16 bank selection terminals to the respective chip enable terminal CE0 of each of the first NAND type flash memory module 211, the second NAND type flash memory module 212, the third NAND type flash memory module 213, the fourth NAND type flash memory module 214, the fifth NAND type flash memory module 215, the sixth NAND type flash memory module 216, the seventh NAND type flash memory module 217, and the eighth NAND type flash memory module 218 at first, and then averagely and separately couple the other 8 bank selection terminals B8, B9, B10, B11, B12, B13, B14, and B15 of the 16 bank selection terminals to the respective chip enable terminal CE1 of each of the first NAND type flash memory module 211, the second NAND type flash memory module 212, the third NAND type flash memory module 213, the fourth NAND type flash memory module 214, the fifth NAND type flash memory module 215, the sixth NAND type flash memory module 216, the seventh NAND type flash memory module 217, and the eighth NAND type flash memory module 218, as shown in FIG. 3. FIG. 3 shows a simplified block diagram of the SSD 200 in accordance with an embodiment of the present invention utilized with the circuit element switching method in accordance with the first embodiment of the present invention together. Please note herein that the above embodiment is only for illustration purposes and is not meant to be a limitation of the present invention. For example, when the SSD 200 only includes the first NAND type flash memory module 211, the second NAND type flash memory module 212, the third NAND type flash memory module 213, and the fourth NAND type flash memory module 214, the technical content disclosed by the present invention is suitable to be applied in this condition.

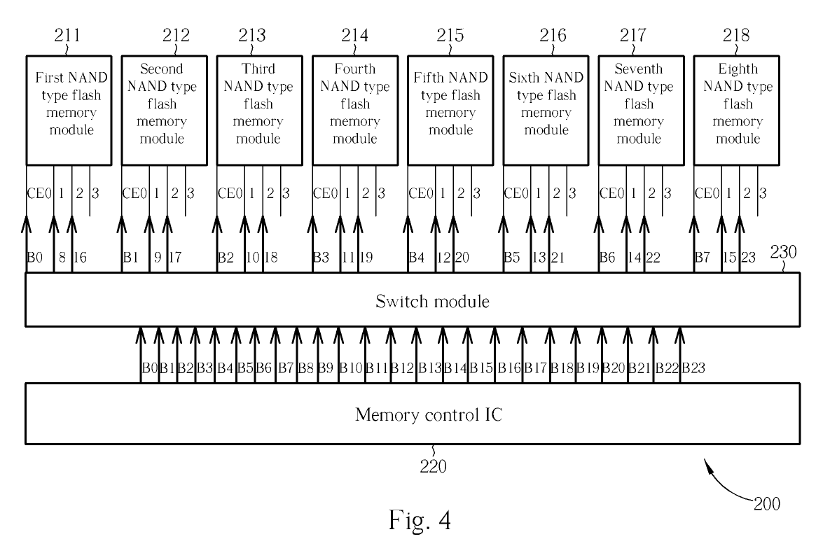

Next, when there are only three chip enable terminals CE0, CE1, and CE2 in the respective four chip enable terminals CE0, CE1, CE2, and CE3 of each of the first NAND type flash memory module 211, the second NAND type flash memory module 212, the third NAND type flash memory module 213, the fourth NAND type flash memory module 214, the fifth NAND type flash memory module 215, the sixth NAND type flash memory module 216, the seventh NAND type flash memory module 217, and the eighth NAND type flash memory module 218 are respectively coupled to a NAND type flash memory chip (not shown) and the other one chip enable terminal CE3 is left unused for the moment, then reasoning by analogy, the SSD 200 and the circuit element switching method in accordance with the first embodiment of the present invention can efficiently make use of the respective three NAND type flash memory chips of each of the first NAND type flash memory module 211, the second NAND type flash memory module 212, the third NAND type flash memory module 213, the fourth NAND type flash memory module 214, the fifth NAND type flash memory module 215, the sixth NAND type flash memory module 216, the seventh NAND type flash memory module 217, and the eighth NAND type flash memory module 218 by only utilizing the memory control IC 220 having 24 bank selection terminals B0, B1, B2, B3, B4, B5, B6, B7, B8, B9, B10, B11, B12, B13, B14, B15, B16, B17, B18, B19, B20, B21, B22, and B23 and the switch module 230, so as to attain a maximum storage capacity. Wherein, the circuit element switching method in accordance with the first embodiment of the present invention utilizes the switch module 230 in the SSD 200 to averagely and separately couple the 8 bank selection terminals B0, B1, B2, B3, B4, B5, B6, and B7 of the 24 bank selection terminals to the respective chip enable terminal CE0 of each of the first NAND type flash memory module 211, the second NAND type flash memory module 212, the third NAND type flash memory module 213, the fourth NAND type flash memory module 214, the fifth NAND type flash memory module 215, the sixth NAND type flash memory module 216, the seventh NAND type flash memory module 217, and the eighth NAND type flash memory module 218 at first, and then averagely and separately couple the other 8 bank selection terminals B8, B9, B10, B11, B12, B13, B14, and B15 of the 24 bank selection terminals to the respective chip enable terminal CE1 of each of the first NAND type flash memory module 211, the second NAND type flash memory module 212, the third NAND type flash memory module 213, the fourth NAND type flash memory module 214, the fifth NAND type flash memory module 215, the sixth NAND type flash memory module 216, the seventh NAND type flash memory module 217, and the eighth NAND type flash memory module 218, and averagely and separately couple the other 8 bank selection terminals B16, B17, B18, B19, B20, B21, B22, and B23 of the 24 bank selection terminals to the respective chip enable terminal CE2 of each of the first NAND type flash memory module 211, the second NAND type flash memory module 212, the third NAND type flash memory module 213, the fourth NAND type flash memory module 214, the fifth NAND type flash memory module 215, the sixth NAND type flash memory module 216, the seventh NAND type flash memory module 217, and the eighth NAND type flash memory module 218 in the end, as shown in FIG. 4. FIG. 4 shows a simplified block diagram of the SSD 200 in accordance with an embodiment of the present invention utilized with the circuit element switching method in accordance with the first embodiment of the present invention together. Please note herein that the above embodiment is only for illustration purposes and is not meant to be a limitation of the present invention. For example, when the SSD 200 only includes the first NAND type flash memory module 211, the second NAND type flash memory module 212, the third NAND type flash memory module 213, the fourth NAND type flash memory module 214, the fifth NAND type flash memory module 215, and the sixth NAND type flash memory module 216, the technical content disclosed by the present invention is suitable to be applied in this condition.

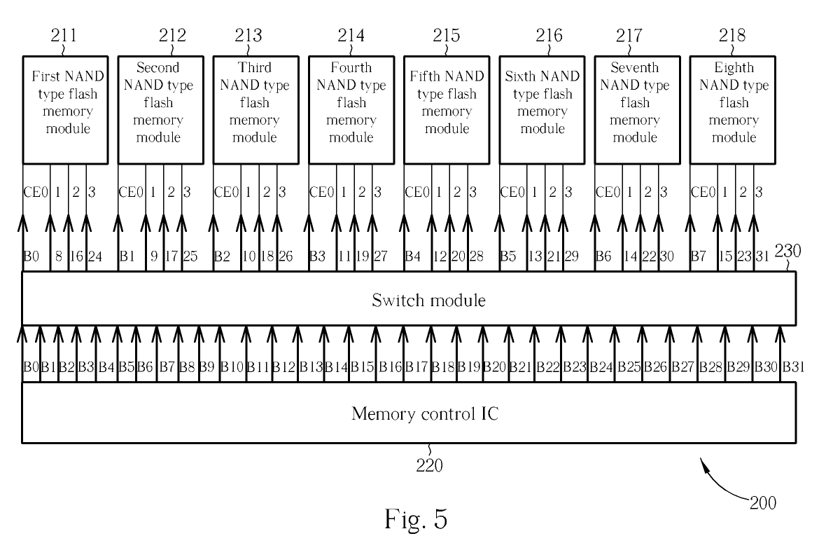

In addition, when all of the respective four chip enable terminals CE0, CE1, CE2, and CE3 of each of the first NAND type flash memory module 211, the second NAND type flash memory module 212, the third NAND type flash memory module 213, the fourth NAND type flash memory module 214, the fifth NAND type flash memory module 215, the sixth NAND type flash memory module 216, the seventh NAND type flash memory module 217, and the eighth NAND type flash memory module 218 are respectively coupled to a NAND type flash memory chip (not shown), then reasoning by analogy, the SSD 200 and the circuit element switching method in accordance with the first embodiment of the present invention can efficiently make use of the respective three NAND type flash memory chips of each of the first NAND type flash memory module 211, the second NAND type flash memory module 212, the third NAND type flash memory module 213, the fourth NAND type flash memory module 214, the fifth NAND type flash memory module 215, the sixth NAND type flash memory module 216, the seventh NAND type flash memory module 217, and the eighth NAND type flash memory module 218 by only utilizing the memory control IC 220 having 32 bank selection terminals B0, B1, B2, B3, B4, B5, B6, B7, B8, B9, B10, B11, B12, B13, B14, B15, B16, B17, B18, B19, B20, B21, B22, B23, B24, B25, B26, B27, B28, B29, B30, and B31 and the switch module 230, so as to attain a maximum storage capacity. Wherein, the circuit element switching method in accordance with the first embodiment of the present invention utilizes the switch module 230 in the SSD 200 to averagely and separately couple the 8 bank selection terminals B0, B1, B2, B3, B4, B5, B6, and B7 of the 32 bank selection terminals to the respective chip enable terminal CE0 of each of the first NAND type flash memory module 211, the second NAND type flash memory module 212, the third NAND type flash memory module 213, the fourth NAND type flash memory module 214, the fifth NAND type flash memory module 215, the sixth NAND type flash memory module 216, the seventh NAND type flash memory module 217, and then the eighth NAND type flash memory module 218 at first, and then averagely and separately couple the other 8 bank selection terminals B8, B9, B10, B11, B12, B13, B14, and B15 of the 32 bank selection terminals to the respective chip enable terminal CE1 of each of the first NAND type flash memory module 211, the second NAND type flash memory module 212, the third NAND type flash memory module 213, the fourth NAND type flash memory module 214, the fifth NAND type flash memory module 215, the sixth NAND type flash memory module 216, the seventh NAND type flash memory module 217, and the eighth NAND type flash memory module 218, and then averagely and separately couple the other 8 bank selection terminals B16, B17, B18, B19, B20, B21, B22, and B23 of the 32 bank selection terminals to the respective chip enable terminal CE2 of each of the first NAND type flash memory module 211, the second NAND type flash memory module 212, the third NAND type flash memory module 213, the fourth NAND type flash memory module 214, the fifth NAND type flash memory module 215, the sixth NAND type flash memory module 216, the seventh NAND type flash memory module 217, and the eighth NAND type flash memory module 218, and averagely and separately couple the other 8 bank selection terminals B24, B25, B26, B27, B28, B29, B30, and B31 of the 32 bank selection terminals to the respective chip enable terminal CE3 of each of the first NAND type flash memory module 211, the second NAND type flash memory module 212, the third NAND type flash memory module 213, the fourth NAND type flash memory module 214, the fifth NAND type flash memory module 215, the sixth NAND type flash memory module 216, the seventh NAND type flash memory module 217, and the eighth NAND type flash memory module 218 in the end, as shown in FIG. 5. FIG. 5 shows a simplified block diagram of the SSD 200 in accordance with an embodiment of the present invention utilized with the circuit element switching method in accordance with the first embodiment of the present invention together. Please note herein that the above embodiment is only for illustration purposes and is not meant to be a limitation of the present invention. For example, when the first NAND type flash memory module 211, the second NAND type flash memory module 212, the third NAND type flash memory module 213, the fourth NAND type flash memory module 214, the fifth NAND type flash memory module 215, the sixth NAND type flash memory module 216, the seventh NAND type flash memory module 217, and the eighth NAND type flash memory module 218 respectively include a greater amount of chip enable terminals, the technical content disclosed by the present invention is suitable to be applied in this condition.

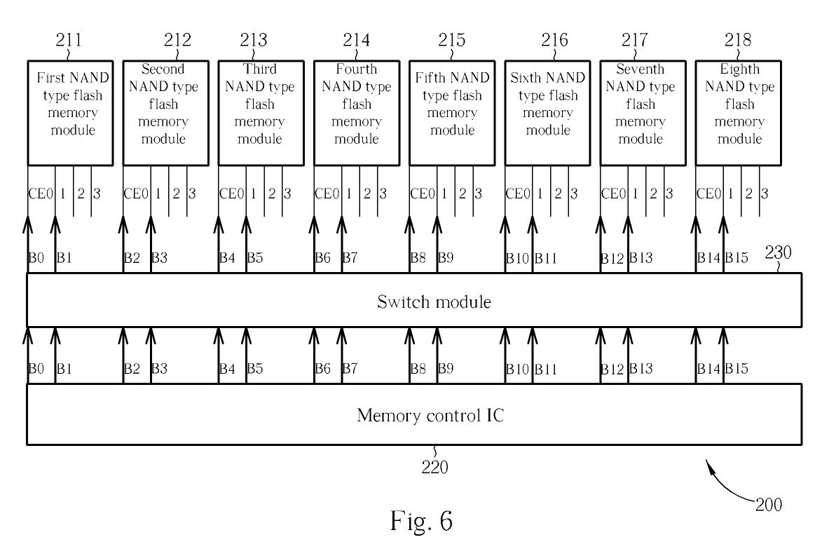

On the other hand, similar with the circuit element switching method in accordance with the first embodiment in the present invention, a circuit element switching method in accordance with a second embodiment of the present invention also can be applied in the SSD 200 shown in FIG. 3, and thus a further explanation of the operational details and the configuration details for the SSD 200 is omitted herein for the sake of brevity. However, the circuit element switching method in accordance with the second embodiment of the present invention utilizes the switch module 230 in the SSD 200 to separately couple the 2 bank selection terminals B0 and B1 of the 16 bank selection terminals to the chip enable terminals CE0 and CE1 of the first NAND type flash memory module 211, and then separately couple the other 2 bank selection terminals B2 and B3 of the 16 bank selection terminals to the chip enable terminals CE0 and CE1 of the second NAND type flash memory module 212, and then separately couple the other 2 bank selection terminals B4 and B5 of the 16 bank selection terminals to the chip enable terminals CE0 and CE1 of the third NAND type flash memory module 213, and then separately couple the other 2 bank selection terminals B6 and B7 of the 16 bank selection terminals to the chip enable terminals CE0 and CE1 of the fourth NAND type flash memory module 214, and couple the other 2 bank selection terminals B8 and B9 of the 16 bank selection terminals to the chip enable terminals CE0 and CE1 of the fifth NAND type flash memory module 215, and then separately couple the other 2 bank selection terminals B10 and B11 of the 16 bank selection terminals to the chip enable terminals CE0 and CE1 of the sixth NAND type flash memory module 216, and then separately couple the other 2 bank selection terminals B12 and B13 of the 16 bank selection terminals to the chip enable terminals CE0 and CE1 of the seventh NAND type flash memory module 217, and separately couple the other 2 bank selection terminals B14 and B15 of the 16 bank selection terminals to the chip enable terminals CE0 and CE1 of the eighth NAND type flash memory module 218 in the end, as shown in FIG. 6. FIG. 6 shows a simplified block diagram of the SSD 200 in accordance with an embodiment of the present invention utilized with the circuit element switching method in accordance with the second embodiment of the present invention together. Please note herein that the above embodiment is only for illustration purposes and is not meant to be a limitation of the present invention. For example, when the SSD 200 only includes the first NAND type flash memory module 211, the second NAND type flash memory module 212, the third NAND type flash memory module 213, and the fourth NAND type flash memory module 214, the technical content disclosed by the present invention is suitable to be applied in this condition.

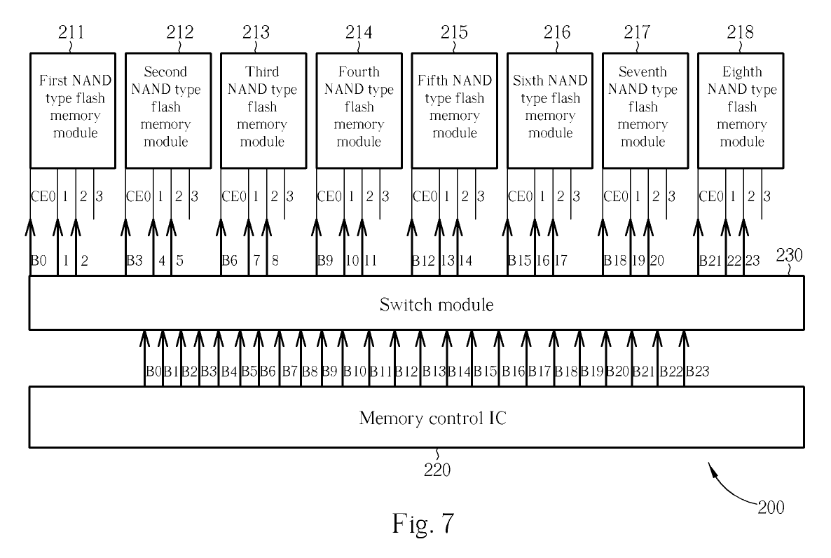

Next, similar with the circuit element switching method in accordance with the first embodiment in the present invention, the circuit element switching method in accordance with the second embodiment of the present invention also can be applied in the SSD 200 shown in FIG. 4, and thus a further explanation of the operational details and the configuration details for the SSD 200 is omitted herein for the sake of brevity. However, the circuit element switching method in accordance with the second embodiment of the present invention utilizes the switch module 230 in the SSD 200 to separately couple the 3 bank selection terminals B0, B1, and B2 of the 24 bank selection terminals to the chip enable terminals CE0, CE1, and CE2 of the first NAND type flash memory module 211, and then separately couple the other 3 bank selection terminals B3, B4, and B5 of the 24 bank selection terminals to the chip enable terminals CE0, CE1, and CE2 of the second NAND type flash memory module 212, and then separately couple the other 3 bank selection terminals B6, B7, and B8 of the 24 bank selection terminals to the chip enable terminals CE0, CE1, and CE2 of the third NAND type flash memory module 213, and then separately couple the other 3 bank selection terminals B9, B10, and B11 of the 24 bank selection terminals to the chip enable terminals CE0, CE1, and CE2 of the fourth NAND type flash memory module 214, and then separately couple the other 3 bank selection terminals B12, B13, and B14 of the 24 bank selection terminals to the chip enable terminals CE0, CE1, and CE2 of the fifth NAND type flash memory module 215, and then separately couple the other 3 bank selection terminals B15, B16, and B17 of the 24 bank selection terminals to the chip enable terminals CE0, CE1, and CE2 of the sixth NAND type flash memory module 216, and then separately couple the other 3 bank selection terminals B18, B19, and B20 of the 24 bank selection terminals to the chip enable terminals CE0, CE1, and CE2 of the seventh NAND type flash memory module 217, and separately couple the other 3 bank selection terminals B21, B22, and B23 of the 24 bank selection terminals to the chip enable terminals CE0, CE1, and CE2 of the eighth NAND type flash memory module 218 in the end, as shown in FIG. 7. FIG. 7 shows a simplified block diagram of the SSD 200 in accordance with an embodiment of the present invention utilized with the circuit element switching method in accordance with the second embodiment of the present invention together. Please note herein that the above embodiment is only for illustration purposes and is not meant to be a limitation of the present invention. For example, when the SSD 200 only includes the first NAND type flash memory module 211, the second NAND type flash memory module 212, the third NAND type flash memory module 213, and the fourth NAND type flash memory module 214, the technical content disclosed by the present invention is suitable to be applied in this condition. Please note herein that the above embodiment is only for illustration purposes and is not meant to be a limitation of the present invention. For example, when the SSD 200 only includes the first NAND type flash memory module 211, the second NAND type flash memory module 212, the third NAND type flash memory module 213, the fourth NAND type flash memory module 214, the fifth NAND type flash memory module 215, and the sixth NAND type flash memory module 216, the technical content disclosed by the present invention is suitable to be applied in this condition.

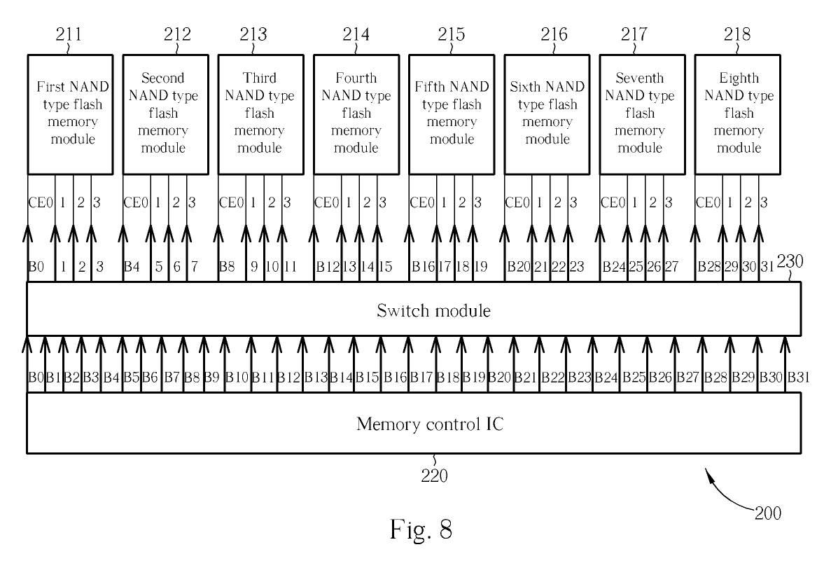

In addition, similar with the circuit element switching method in accordance with the first embodiment in the present invention, the circuit element switching method in accordance with the second embodiment of the present invention also can be applied in the SSD 200 shown in FIG. 5, and thus a further explanation of the operational details and the configuration details for the SSD 200 is omitted herein for the sake of brevity. However, the circuit element switching method in accordance with the second embodiment of the present invention utilizes the switch module 230 in the SSD 200 to separately couple the 4 bank selection terminals B0, B1, B2, and B3 of the 32 bank selection terminals to the chip enable terminals CE0, CE1, CE2, and CE3 of the first NAND type flash memory module 211, and then separately couple the other 4 bank selection terminals B4, B5, B6, and B7 of the 32 bank selection terminals to the chip enable terminals CE0, CE1, CE2, and CE3 of the second NAND type flash memory module 212, and then separately couple the other 4 bank selection terminals B8, B9, B10, and B11 of the 32 bank selection terminals to the chip enable terminals CE0, CE1, CE2, and CE3 of the third NAND type flash memory module 213, and then separately couple the other 4 bank selection terminals B12, B13, B14, and B15 of the 32 bank selection terminals to the chip enable terminals CE0, CE1, CE2, and CE3 of the fourth NAND type flash memory module 214, and then separately couple the other 4 bank selection terminals B16, B17, B18, and B19 of the 32 bank selection terminals to the chip enable terminals CE0, CE1, CE2, and CE3 of the fifth NAND type flash memory module 215, and then separately couple the other 4 bank selection terminals B20, B21, B22, and B23 of the 32 bank selection terminals to the chip enable terminals CE0, CE1, CE2, and CE3 of the sixth NAND type flash memory module 216, and then separately couple the other 4 bank selection terminals B24, B25, B26, and B27 of the 32 bank selection terminals to the chip enable terminals CE0, CE1, CE2, and CE3 of the seventh NAND type flash memory module 217, and separately the other 4 bank selection terminals B28, B29, B30, and B31 of the 32 bank selection terminals to the chip enable terminals CE0, CE1, CE2, and CE3 of the eighth NAND type flash memory module 218 in the end, as shown in FIG. 8. FIG. 8 shows a simplified block diagram of the SSD 200 in accordance with an embodiment of the present invention utilized with the circuit element switching method in accordance with the second embodiment of the present invention together. Please note herein that the above embodiment is only for illustration purposes and is not meant to be a limitation of the present invention. For example, when the SSD 200 only includes the first NAND type flash memory module 211, the second NAND type flash memory module 212, the third NAND type flash memory module 213, and the fourth NAND type flash memory module 214, the technical content disclosed by the present invention is suitable to be applied in this condition. Please note herein that the above embodiment is only for illustration purposes and is not meant to be a limitation of the present invention. For example, when the first NAND type flash memory module 211, the second NAND type flash memory module 212, the third NAND type flash memory module 213, the fourth NAND type flash memory module 214, the fifth NAND type flash memory module 215, the sixth NAND type flash memory module 216, the seventh NAND type flash memory module 217, and the eighth NAND type flash memory module 218 respectively include a greater amount of chip enable terminals, the technical content disclosed by the present invention is suitable to be applied in this condition.

In any case, the most important spirit of the technical content disclosed by the present invention is providing a storage device and a circuit element switching method thereof that are capable of utilizing an interconnection scheme with elastic flexibility to averagely and separately couple a specific amount of bank selection terminals to a plurality of chip enable terminals of each of a plurality of memory modules, and thus a person of average skill in the pertinent art should be able to easily understand that various modifications and alterations of the device and method should fall into the disclosed scope of the present invention as long as they are able to averagely and separately couple the specific amount of bank selection terminals to the plurality of chip enable terminals of each of the plurality of memory modules.

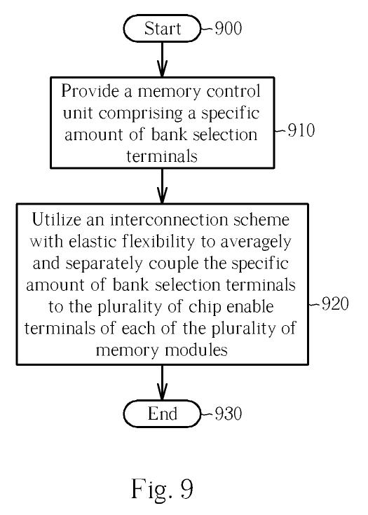

Please refer to FIG. 9. FIG. 9 is a flowchart showing a circuit element switching method applied to a storage device in accordance with the operation schemes of the SSD 200 in the above embodiments of the present invention, wherein the storage device includes a plurality of memory modules (that can include a plurality of non-volatile memory modules, such as the NAND type flash memory modules), and each of the plurality of memory modules includes a plurality of chip enable terminals. Provided that substantially the same result is achieved, the steps of the process flowchart need not be in the exact order shown and need not be contiguous, that is, other steps can be intermediate. The circuit element switching method applied to the storage device according to the present invention includes the following steps:

Step 900: Start.

Step 910: Provide a memory control unit comprising a specific amount of bank selection terminals.

Step 920: Utilize an interconnection scheme with elastic flexibility to averagely and separately couple the specific amount of bank selection terminals to the plurality of chip enable terminals of each of the plurality of memory modules.

Step 930: End.

In addition, no matter which kind of memory module is selected, as long as the memory module has two or more than two chip enable terminals, then the present invention can utilize an interconnection scheme with elastic flexibility to let various different combinations all be able to properly map and interconnect with each other.

Briefly summarized, the storage device and the conventional circuit element switching method thereof disclosed by the present invention are obviously capable of attaining the maximum storage capacity in the various different product design schemes nowadays, and thus the storage device and the conventional circuit element switching method thereof disclosed by the present invention are able to satisfy the various different requirements brought by the considerations based on the product cost, trends of the market preferences, and upgrading product lines in the future of the most SSD manufacturers.

Those skilled in the art will readily observe that numerous modifications and alterations of the device and method may be made while retaining the teachings of the invention.

What is claimed is:

1. A storage device, comprising:
a plurality of memory modules, each comprising a plurality of chip enable terminals;
a memory control unit, comprising a specific amount of bank selection terminals; and
a switch module, coupled between the plurality of memory modules and the memory control unit, for dispersedly coupling the specific amount of bank selection terminals to the plurality of chip enable terminals of each memory module.

2. The storage device of claim 1, wherein the switch module averagely and separately couples the specific amount of bank selection terminals to the plurality of chip enable terminals of each memory module.

3. The storage device of claim 1, wherein the switch module utilizes an interconnection scheme with elastic flexibility to dispersedly couple the specific amount of bank selection terminals to the plurality of chip enable terminals of each memory module.

4. The storage device of claim 1, wherein the memory control unit is utilized for controlling the switch module to perform a re-mapping interconnection operation on each memory module.

5. The storage device of claim 1, wherein the plurality of memory modules comprises a plurality of non-volatile memory modules.

6. The storage device of claim 5, wherein the plurality of non-volatile memory modules comprises a plurality of NAND type flash memory modules.

7. The storage device of claim 1, comprising a solid state drive (SSD).

8. A circuit element switching method applied to a storage device comprising a plurality of memory modules each comprising a plurality of chip enable terminals, the circuit element switching method comprising:
providing a memory control unit comprising a specific amount of bank selection terminals; and
dispersedly coupling the specific amount of bank selection terminals to a plurality of chip enable terminals of each memory module.

9. The circuit element switching method of claim 8, wherein the step of dispersedly coupling the plurality of bank selection terminals to the plurality of chip enable terminals of each memory module further comprises:
averagely and separately coupling the specific amount of bank selection terminals to the plurality of chip enable terminals of each memory module.

10. The circuit element switching method of claim 8, wherein the step of dispersedly coupling the plurality of bank selection terminals to the plurality of chip enable terminals of each memory module further comprises:
utilizing an interconnection scheme with elastic flexibility to dispersedly couple the specific amount of bank selection terminals to the plurality of chip enable terminals of each memory module.

11. The circuit element switching method of claim 8, further comprising:
performing a re-mapping interconnection operation on each memory module.

12. The circuit element switching method of claim 8, wherein the plurality of memory modules comprises a plurality of non-volatile memory modules.

13. The circuit element switching method of claim 12, wherein the plurality of non-volatile memory modules comprises a plurality of NAND type flash memory modules.

14. The circuit element switching method of claim 8, wherein the storage device comprises a solid state drive.
